(19) United States
(12) Patent Application Publication
(10) Pub. No.: US 2015/0091620 A1
(43) Pub. Date: Apr. 2, 2015

(54) REDUCING CURRENT VARIATION WHEN SWITCHING CLOCKS

(71) Applicant: LSI Corporation, San Jose, CA (US)

(72) Inventor: Steven J. Pollock, Allentown, PA (US)

(73) Assignee: LSI Corporation, San Jose, CA (US)

(21) Appl. No.: 14/045,295

(22) Filed: Oct. 3, 2013

Related U.S. Application Data
(60) Provisional application No. 61/885,169, filed on Oct. 1, 2013.

(51) Int. Cl. H03K 17/16

(52) U.S. Cl. CPC H03K 17/16
USPC 327/117

(57) ABSTRACT

An apparatus includes a glitchless divider and a glitchless multiplexer. The glitchless divider may be configured to generate a first system clock in response to a divider value and a clock signal received from a first source. The divider value changes from a first value to a second value in a predetermined number of steps. The glitchless multiplexer may be configured to select between said first system clock and a second system clock in response to a control signal.

This application relates to U.S. Provisional Application No. 61/885,169, filed Oct. 1, 2013, which is hereby incorporated by reference in its entirety.

### FIELD OF THE INVENTION

The invention relates to clock switching in electronic circuits generally and, more particularly, to a method and/or apparatus for reducing current variation (dI/dt) when switching clocks.

### BACKGROUND

As application specific integrated circuit (ASIC) designs become larger, more and more state logic is being included in clock domains. When a large number of state elements are clocked by a clock that can have multiple sources, switching from using a lower frequency clock to a higher frequency clock or vice versa can result in large current swings (dI/dt) on the device. Large current variations can tax the power supply and result in local voltage drops that can impact the speed of the logic circuits and even result in a timing failure on the device.

It would be desirable to have a method and/or apparatus for reducing current variation (dI/dt) when switching clocks to alleviate these issues.

### SUMMARY

The invention concerns an apparatus including a glitchless divider and a glitchless multiplexer. The glitchless divider may be configured to generate a first system clock in response to a divider value and a clock signal received from a first source. The divider value changes from a first value to a second value in a predetermined number of steps. The glitchless multiplexer may be configured to select between said first system clock and a second system clock in response to a control signal.

### BRIEF DESCRIPTION OF THE FIGURES

Embodiments of the invention will be apparent from the following detailed description and the appended claims and drawings in which:

FIG. 1 is a diagram illustrating an integrated circuit in accordance with an embodiment of the invention;

FIG. 2 is a diagram illustrating an example implementation of a clock switching circuit of FIG. 1;

FIG. 3 is a diagram illustrating an example implementation of a glitchless divider of FIG. 2;

FIG. 4 is a timing diagram illustrating an example operation of the glitchless divider of FIG. 3;

FIG. 5 is a diagram illustrating another example implementation of the clock switching circuit of FIG. 1;

FIG. 6 is a timing diagram illustrating an example operation of the clock switching circuit of FIG. 5;

FIG. 7 is a diagram illustrating an example implementation of the glitchless divider of FIG. 2 that provides a 50 percent duty cycle;

FIG. 8 is a timing diagram illustrating an example operation of the glitchless divider of FIG. 7;

FIG. 9 is a diagram illustrating an example implementation of a glitchless multiplexer in accordance with an embodiment of the invention;

FIG. 10 is a flow diagram illustrating a process for switching from a slow clock to a fast clock in accordance with an embodiment of the invention; and

FIG. 11 is a flow diagram illustrating a process for switching from a fast clock to a slow clock in accordance with an embodiment of the invention.

### DETAILED DESCRIPTION OF THE EMBODIMENTS

Embodiments of the invention include providing a method for reducing current variation (dI/dt) when switching clocks that may (i) be implemented with minimal added logic, (ii) switch between two clock frequencies using a plurality of smaller frequency changes, (iii) allow stepping up or down from a current clock frequency to a higher or lower frequency, respectively, (iv) result in reduced dI/dt swings, and/or (v) be implemented as one or more integrated circuits.

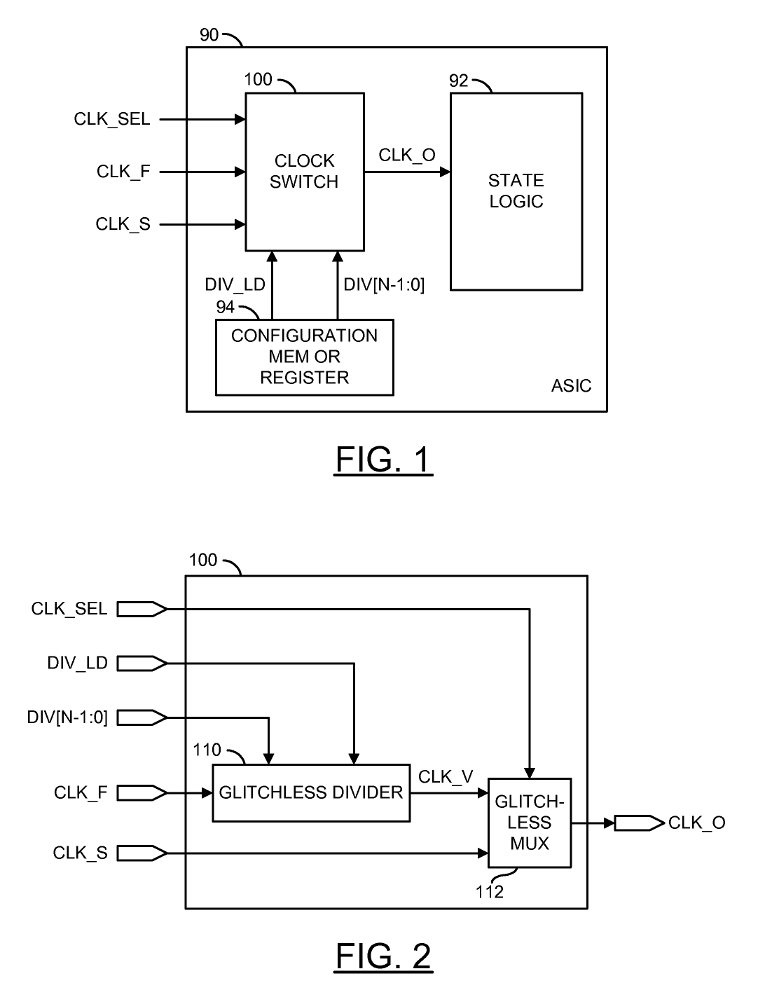

Referring to FIG. 1, a diagram of a circuit 90 is shown including a clock switching circuit in accordance with an embodiment of the invention. The circuit 90 may be implemented as one or more application specific integrated circuits (ASICs). The circuit 90 may comprise one or more blocks 92, one or more blocks 94, and a block 100. In various embodiments, the one or more blocks 92 implement state logic, the one or more blocks 94 implement configuration memory and/or registers, and the block 100 implements a clock switching circuit in accordance with an embodiment of the invention. The state logic of the one or more blocks 92 may be clocked by a clock signal (e.g., CLK_O) generated by the block 100. The one or more blocks 94 may be programmed to configure various operating parameters and/or operations of the circuit 90, including operations of the block 100.

In various embodiments, the block 100 is configured to generate the clock signal CLK_O in response to a selected one of a plurality of input clock signals. The plurality of input clock signals may be received from (or generated by) a plurality of sources. In various embodiments, the circuit 100 is configured to select between the plurality of input clock signals based upon a control signal (e.g., CLK_SEL). In some embodiments, the circuit 100 is configured to switch between a first clock signal (e.g., CLK_S) and a second clock signal (e.g., CLK_F) based upon the control signal CLK_SEL. The clock signal CLK_F generally has a significantly higher frequency than the clock signal CLK_S. In various embodiments, the frequency of the clock signal CLK_F and the clock signal CLK_S may differ by one or more orders of magnitude. For example, the clock signal CLK_S may be implemented with a frequency of 100 MHz and the clock signal CLK_F may be implemented with a frequency of 1 GHz.

In various embodiments, the circuit 100 is enabled to switch from one clock frequency to a faster or slower clock frequency. This causes a corresponding change in current (dI/dt) to meet the demands of all the downstream logic blocks 92 now switching at the higher or lower clock frequency. If the amount of logic running on the clock is significant, when the clock signal CLK_O switches from the slower clock frequency to the faster clock frequency or vice versa, the resulting change in current (dI/dt) can be quite large. If the power supply or power distribution infrastructure cannot meet the instantaneous current change demanded as a result of switching between the clocks, a dip (or droop) in the internal voltage of the circuit 90 can result, which may or may not result in a functional device failure. If a conventional clock switch is used in applications similar to the above example, the frequency increase is actually magnified, because in a conventional clock switch the clock rests at a single phase value for multiple clock cycles during the switch from one clock to the other. Thus, the effective clock frequency seen by the downstream logic is actually less than the actual frequency of the slower clock and the resulting frequency change when switching to the faster clock is then greater than the difference between the two clocks.

The circuit 100 is generally configured to reduce the current variation dI/dt due to switching clocks by walking up or down to the new frequency in a series of steps with smaller frequency changes. In various embodiments, the circuit 100 has a first input that receives a signal (e.g., DIV[N−1:0]) and a second input that receives a signal (e.g., DIV_LD). The number and size of the series of steps is generally determined based upon the signal DIV[N−1:0]. In some embodiments, the signal DIV[N−1:0] is received from the one or more blocks 94. The signal DIV_LD generally implements a control signal for synchronously loading divider values contained in the signal DIV[N−1:0]. The circuit 100 generally allows selection of either the slower frequency clock directly, or a stepped clock output for the faster clock (instead of, or in addition to, the faster clock directly).

Referring to FIG. 2, a diagram is shown illustrating an example implementation of the circuit 100 of FIG. 1. In various embodiments, the circuit 100 comprises a block 110 and a block 112. The block 110 implements a glitchless divider circuit. The block 112 implements a glitchless clock switch (or multiplexer) circuit. The block 110 has a first input that receives the clock signal CLK_F, a second input that receives the signal DIV_LD, and a third input that receives the signal DIV[N−1:0]. The signals DIV_LD and DIV[N−1:0] generally implement control signals for controlling a number and size of frequency change steps that the block 110 takes to move from a first frequency (e.g. a frequency of the signal CLK_S) to a second frequency (e.g. a frequency of the signal CLK_F), and vice versa. The block 110 has an output that presents a signal (e.g., CLK_V).

The block 110 is generally configured to generate the signal CLK_V by dividing the frequency of the signal CLK_F based on the signal DIV[N−1:0]. The signal DIV[N−1:0] is generally varied between a first value and a second value in a number of predetermined steps such that the frequency of the signal CLK_V varies from a frequency approximately equal to the frequency of the signal CLK_S to the frequency of the signal CLK_F, or vice versa. The predetermined number of steps are generally selected to reduce current variation (e.g., dI/dt) caused by the changes in frequency to a minimal amount. The signal DIV_LD is generally configured to synchronize the changes in the value of the signal DIV[N−1:0] to the CLK_F domain.

In various embodiments, the block 112 has a first input that receives the clock signal CLK_S, a second input that receives the signal CLK_V, a control (or select) input that receives the signal CLK_SEL, and an output that presents the signal CLK_O. The block 112 is configured to select either the signal CLK_S or the signal CLK_V as the signal CLK_O in response to the signal CLK_SEL.

In various embodiments, the signal DIV[N−1:0] is generated in the configuration logic 94 that is part of the circuit 90. In some embodiments, however, the signal DIV[N−1:0] is presented on a set of input pins to the circuit 90. In some embodiments, the configuration logic 94 handles the sequence of stepping from a current value to a new value. In some embodiments, the values are sourced from a register that is readable and writable by software. In the register-based embodiments, the software is configured to walk the values by, for example, writing the register in the desired sequence. If the configuration logic 94 is in a different clock domain than the circuit 100, the control signals sent from the block 94 to the circuit 100 need to be synchronized to the clock domain of the circuit 100 before the control signals are used (e.g., by divider logic of the circuit 100). In one example, the signals may be synchronized using the signal DIV_LD sourced from the configuration logic 94.

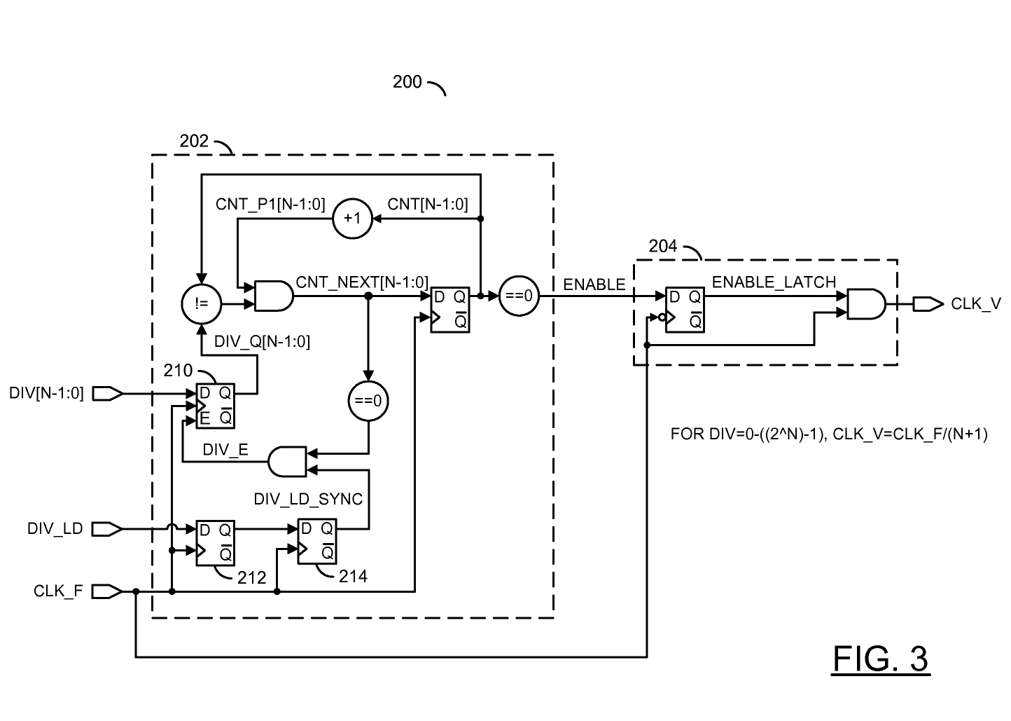

Referring to FIG. 3, a diagram of a circuit 200 is shown illustrating an example implementation of the glitchless divider 110 of FIG. 2. There are many different ways to implement the glitchless divider circuit 110 depending on the needs of the downstream logic 92. If a 50/50 duty cycle on the output clock CLK_O is not important (e.g., all downstream logic 92 is, for example, single edge triggered), then a simple clock gate circuit (e.g., a library element having a negative gate latch in the enable path and an “AND” gate) can be used to knock out selected pulses of the input clock signal CLK_F to generate the output clock signal CLK_V. In some embodiments, the circuit 200 comprises a block (or circuit) 202 and a block (or circuit) 204.

The circuit 202 generally implements digital logic that generates a signal (e.g., ENABLE). The signal ENABLE is used to remove input clock pulses to generate the divided output clock CLK_V. The circuit 202 can be as complex as necessary to generate the desired range of divider values. In some embodiments, the circuit 202 may be parameterized to generate an n-bit counter and accept a compare value from 0 through (2̂n)−1 that controls when the counter resets to 0. The signal ENABLE could be asserted only when the counter is 0. For example, an implementation of the circuit 200 with n=4 would allow integer divide values from 1 to 16 to be generated with compare values from 0 to 15, respectively.

In various embodiments, with the compare value set to 0, the counter 202 remains at 0 and the signal ENABLE remains at 1, which would pass the input clock signal CLK_F as the output clock signal CLK_V, providing a divide-by-1. If the compare value is set to 15, the counter 202 counts 0 to 15 and repeats, and only 1 out of every 16 pulses of the input clock CLK_F is passed to the output clock signal CLK_V, producing a divide-by-16. Setting the compare value to n, the counter 202 counts 0 to n and repeats, passing only 1 out of every (n+1) pulses of the input clock CLK_F, which would generate a divide-by-(n+1) output clock CLK_V (e.g., for DIV[N−1:0]=0−(2̂n)−1), CLK_V=CLK_F/(n+1)). Other non-integer scenarios are also possible with additional control. For example, passing 3 out of every 4 pulses provides a divide_by_{—}1.333 (or 75%) output clock.

In general, the signals that control the enable logic implemented in the block 202 (e.g., counter, compare value, or other control inputs) need to be synchronous to the input clock signal CLK_F. In some embodiments, the signals may be synchronized using the signal DIV_LD sourced from the configuration logic 94. For example, the value of the signal DIV[N−1:0] is changed only when the signal DIV_LD is deasserted. Once the new value of the signal DIV[N−1:0] has had sufficient time to propagate to the D-inputs of an internal register 210 in the clock domain of the circuit 100, the signal DIV_LD is asserted and synchronized into the clock domain of the circuit 100 (e.g., through flip-flops 212 and 214), as illustrated by the signal DIV_LD_SYNC in FIG. 3). The signal DIV_LD then enables the new divider value to be loaded into the internal register 210 and used as the comparison value in the divider logic at a predetermined time (e.g., when the internal counter is going to be loaded with 0). In some embodiments, it may be desirable to react only to a change in the control signals when the internal counter in the block 202 is loading with zero. Limiting reaction only to times when the counter is loading with zero ensures a glitchless output clock if the normal setup/hold timing is met during timing closure for the logic at all process corners.

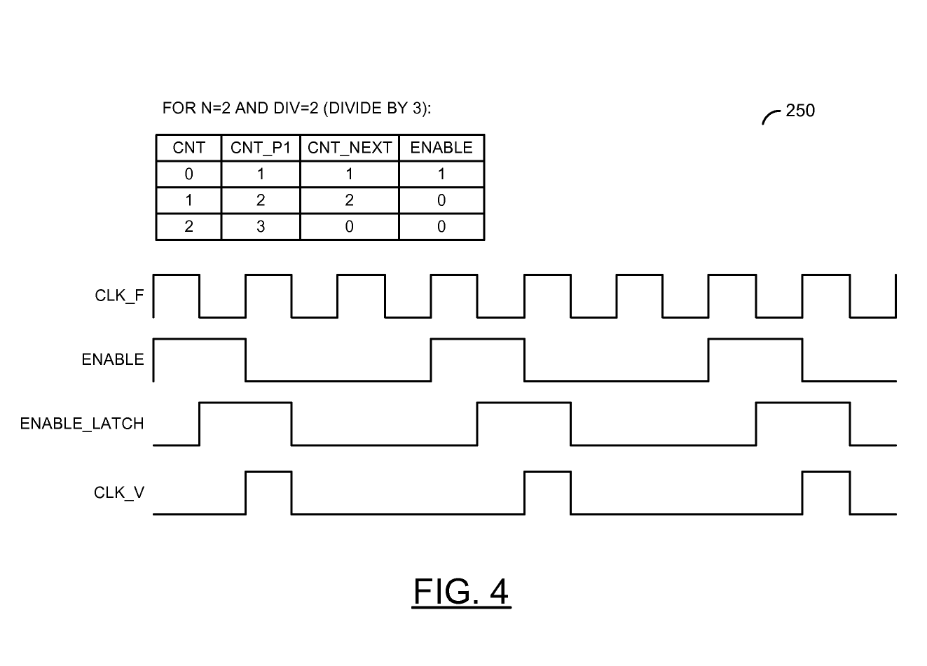

Referring to FIG. 4, a timing diagram 250 is shown illustrating an example operation of the circuit 200 of FIG. 3. In one example, the circuit 200 may be implemented using a 2-bit counter that counts 0->1->2->0->1->2 . . . to generate the enable signal ENABLE. The enable signal ENABLE may then be used to remove every 2 out of 3 input clock pulses to generate a “divide-by-3” output clock.

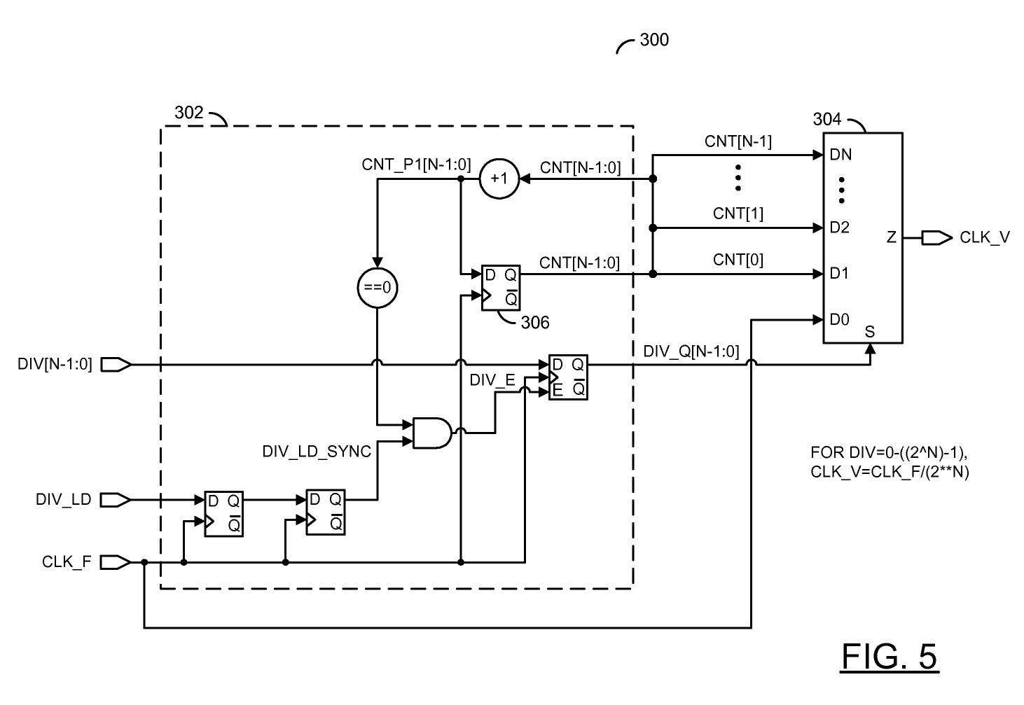

Referring to FIG. 5, a diagram of a circuit 300 is shown illustrating another example implementation of the clock switching circuit 100 of FIG. 1. When a 50/50 duty cycle output clock is desired, a slightly different scheme may be implemented. In various embodiments, the circuit 300 comprises a block (or circuit) 302 and a block (or circuit) 304. The block 302 implements an n-bit counter. The block 304 implements an (n+1) input multiplexer. The simple case of dividing just by powers of 2 can be realized by using the n-bit counter 302 clocked by the input clock signal CLK_F. Bit 0 of a counter register 306 can be used as a first output clock (e.g., CNT[0]), which is a divide-by-2 of the input clock (e.g., the signal CNT[0] toggles every other input clock). Bit 1 of the counter register 306 can be used as a second output clock (e.g., CNT[1]), which is a divide-by-4 of the input clock. Bit 2 of the counter register 306 can be used as a third output clock (e.g., CNT[2]), which is a divide-by-8, etc. The output clock CLK_ V is generated by the multiplexer 304 selecting between the input clock signal CLK_F (e.g., for divide-by-1) or the different counter bits CNT[0], CNT[1], CNT[2], etc., for divide-by-2, 4, 8, 16, etc.

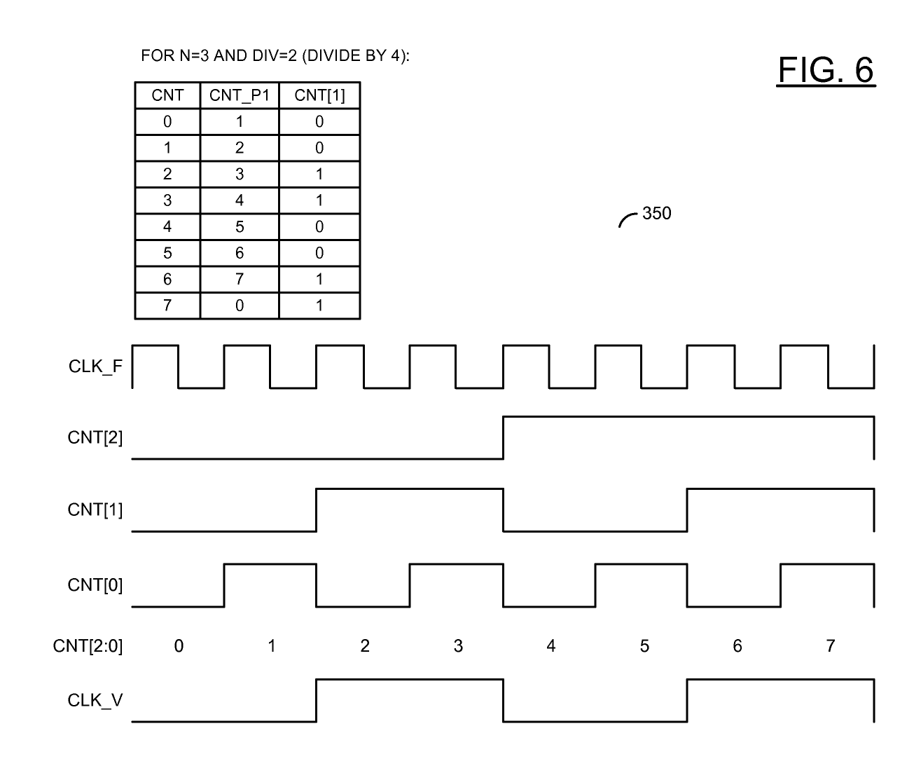

Referring to FIG. 6, a timing diagram 350 is shown illustrating an example operation of the circuit 300 of FIG. 5. In one example, the circuit 300 may be implemented using a 3-bit counter. The signal DIV[N−1:0] may be set to a value of 2 to generate a “divide-by-4” output clock.

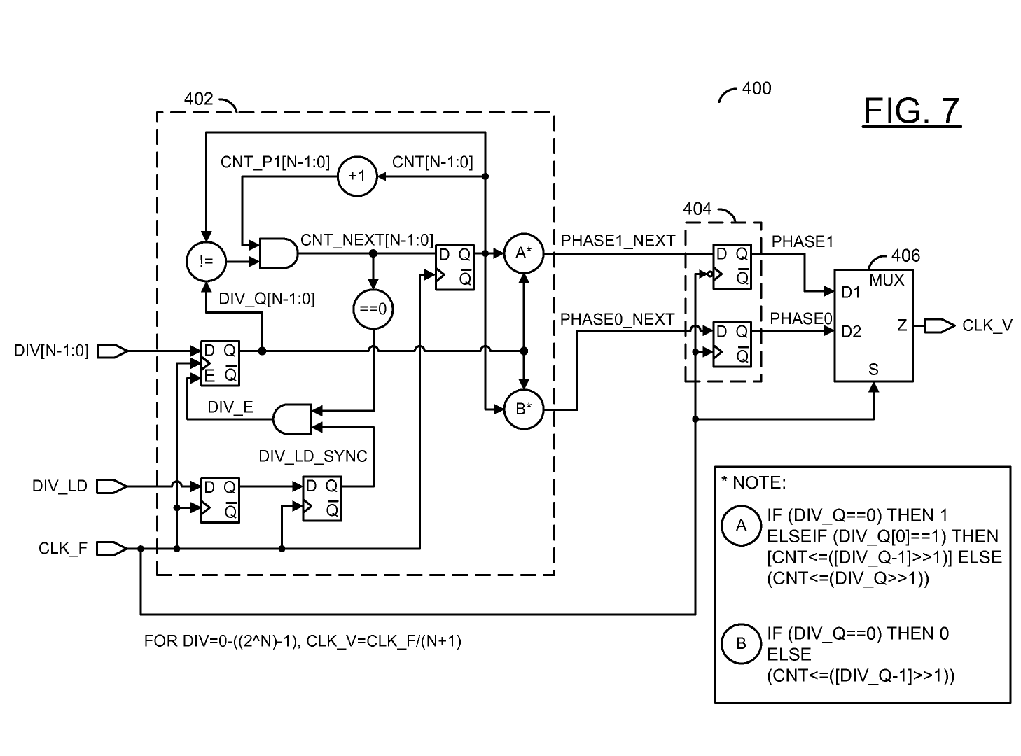

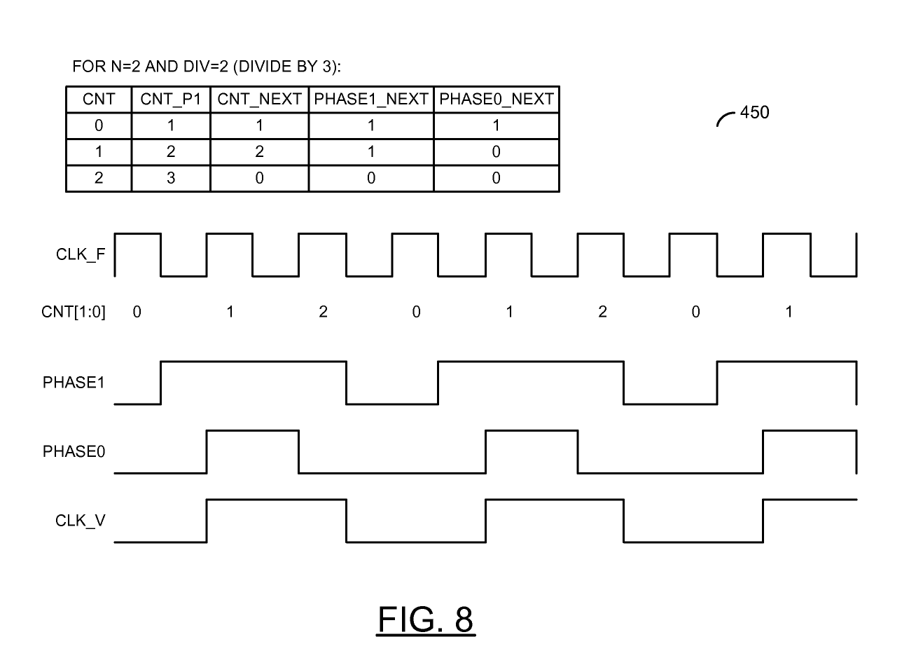

Referring to FIG. 7, a diagram of a circuit 400 is shown illustrating an example implementation of the glitchless divider 110 of FIG. 2 that provides a 50 percent duty cycle. For 50/50 duty cycle output clocks with non-power of 2 dividers, a scheme as shown in FIG. 7 can be used, where the output clock signal CLK_V is generated by a multiplexer 406 that uses the input clock signal CLK_ F as the control input to select between a first phase enable signal (e.g., PHASE1) when the input clock signal CLK_F is HIGH and a second phase enable signal (e.g., PHASE0) when the input clock signal CLK_F is LOW. The signals PHASE1 and PHASE0 are driven appropriately to generate a 50/50 duty cycle output clock waveform.

The circuit 400 may comprise a block (or circuit) 402, a block (or circuit) 404, and a block (or circuit) 406. The blocks 402 and 404 implement phase1/0_next logic that can be as complicated as necessary to generate the desired divider values and can also be parameterized to cover an arbitrary range of divider values. The block 406 implements a multiplexer. The control signals need to be synchronous to the input clock signal CLK_F and it may be desirable to change the control signals only when the counter implemented by the block 402 is resetting to 0. Again, as long as the design is timing closed for normal setup/hold, the logic will function correctly.

Referring to FIG. 8, a timing diagram 450 is shown illustrating an example operation of the circuit 400 of FIG. 7. FIG. 8 shows an example for the same divide-by-3 case as illustrated in FIG. 4, but for the 50/50 duty cycle case.

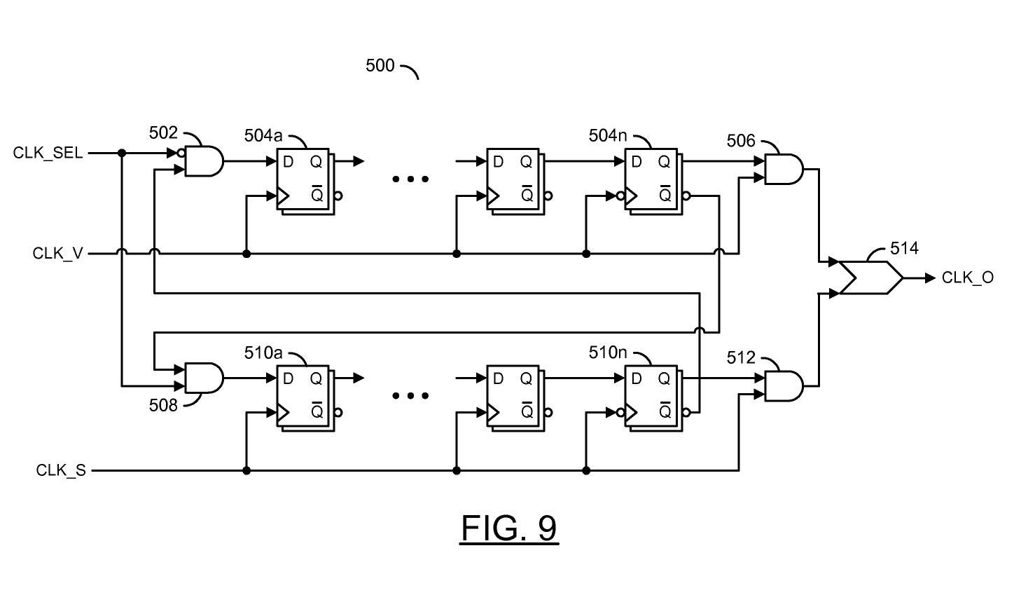

Referring to FIG. 9, a diagram of a circuit 500 is shown illustrating an example implementation of a glitchless clock multiplexer (or switch) circuit in accordance with an embodiment of the invention. In various embodiments, the circuit 500 comprises a logic gate 502, a number of flip-flops 504a-504n, a logic gate 506, a logic gate 508, a number of flip-flops 510a-510n, a logic gate 512, and a logic gate 514. In some embodiments, the logic gates 502, 506, 508, and 512 are implemented as AND gates and the logic gate 514 is implemented as an OR gate. The circuit 500 shows one possible implementation for a 2-to-1 clock switch with an arbitrary number of synchronization stages (e.g., flip-flops 504a-504n and 510a-510n) in the select paths for each of two input clocks (e.g., CLK_V and CLK_S). Basically, when the control input (e.g., CLK_SEL) changes, the enable for the newly selected clock is not allowed to propagate until the enable for the currently selected clock has been deasserted and synchronized to the current clock, resulting in resting the output clock LOW. The enable for the new clock is then allowed to assert and propagate through the synchronization stages for the new clock until the new clock becomes the source of the output clock.

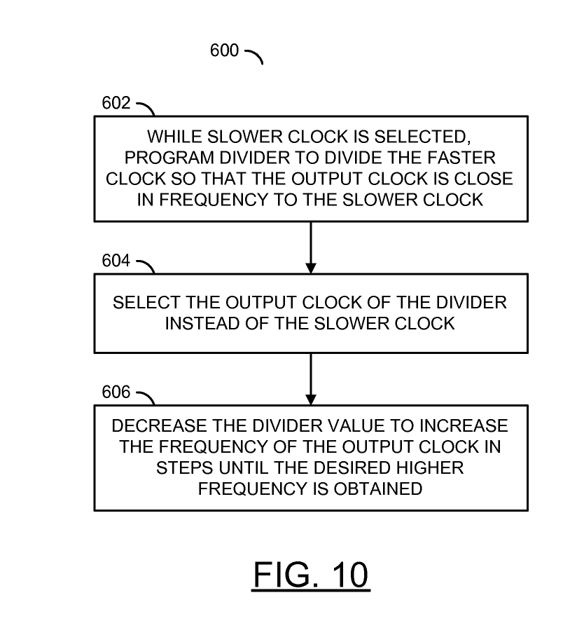

Referring to FIG. 10, a flow diagram of a process 600 is shown illustrating a process in accordance with an embodiment of the invention. The process (or method) 600 generally reduces the current variation dI/dt when switching clocks from a slower clock to a faster clock. Instead of just switching from one clock to the other clock directly (as is done in a conventional system) and seeing the entire frequency change at once, the process 600 generally walks the frequency up to the new frequency in a series of smaller frequency change steps. Most modern phase lock loops (PLLs) allow some form of dynamic frequency dithering or glitchless change in the post divide of the voltage controlled oscillator (VCO) as part of the PLL itself, but often the frequency range changes the conventional mechanisms allow to be covered are not adequate enough to span the entire range from one clock frequency to the other. For those cases, sourcing the downstream clock from a clock switch that allows selection of either the slower frequency clock directly or the output of a programmable glitchless divider for the faster clock (instead of, or in addition to, the faster clock directly) allows the process 600 comprising steps (or states) 602 to 606 to be implemented when switching from the slower clock to the faster clock.

Starting in the step 602 with the clock switch selecting the slower clock signal CLK_S, the process 600 programs the divider to divide the faster clock CLK_F such that the frequency of the clock signal presented at the output of the divider is close to or equal to the frequency of the slower clock CLK_S. In the step 604, the process 600 changes the clock switch select to select the output of the divider. Because of the divider, the magnitude of the frequency switch is significantly reduced. In the step 606, the process 600 decreases the divider value to increase the frequency of the output clock signal (e.g., CLK_V) in a number of predetermined steps until the desired higher frequency is reached.

For example, a change from a 100 MHz clock to a 1000 MHz clock may be accomplished by the following steps. Program the divider value initially to 10 such that the divider is dividing the 1000 MHz faster clock to 100 MHz. When the clock switch is changed to select the divider output instead of the slower clock, the output clock appears to switch from some frequency less than 100 MHz (due to the stretched resting pulse in the clock switch) to the divider output of 100 MHz. The divider could be programmed to be an even lower starting frequency if the “clock switch resting phase” frequency is slow enough to be an issue. If the divider is now decremented from 10 down to 1, the resulting output clock frequency changes would be:
100->111 MHz;
111->125 MHz;
125->142 MHz;
142->167 MHz;
167->200 MHz;
200->250 MHz;
250->333 MHz;
333->500 MHz;
500->1000 MHz.
   The largest frequency change being the final change, which is only a 2× change instead of a 10× change.

If the faster clock is being sourced from a phase locked loop (PLL), the PLL could be programmed to output a higher frequency (e.g., twice, four times, etc.) than the desired clock frequency and with the right divider values, the frequency changes could be reduced further. For example, if the PLL was programmed to output 4 GHz instead of 1 GHz, an initial divider value of 40 could be used to generate a 100 MHz output clock, and the largest frequency change could be from 800 MHz (divider value of 5) to 1000 MHz (divider value of 4) or only a 0.25× maximum change in frequency value.

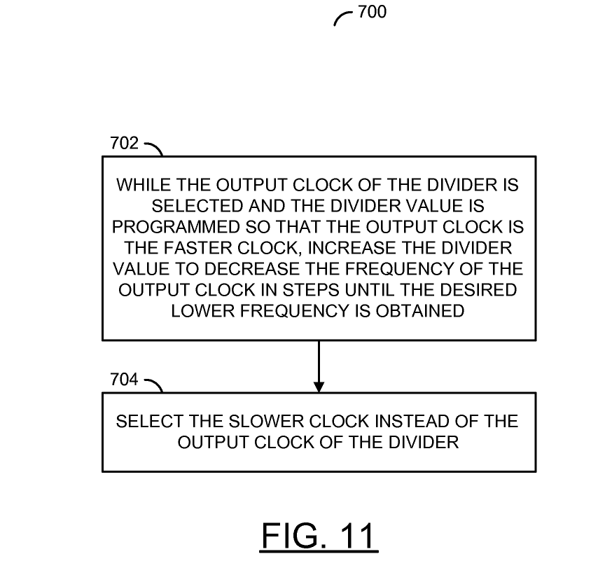

Referring to FIG. 11, a flow diagram of a process 700 is shown illustrating another example process in accordance with an embodiment of the invention. The process (or method) 700 switches from a faster clock to a slower clock. The process 700 can be implemented similarly to the process 600, except that the divider value is incremented to decrease the frequency of the output clock CLK_V. The process 700 generally reduces the current variation dI/dt when switching clocks from a faster clock to a slower clock. Instead of just switching from one clock to the other directly (as is done in a conventional system) and seeing the entire frequency change at once, the process 700 would walk the frequency down to the new frequency in a series of smaller frequency change steps.

Starting in a step 702, with the clock switch selecting the output of the divider (e.g., CLK_V) and the divider value programmed for the faster clock CLK_F, the process 700 changes the divider value such that the frequency of the clock signal CLK_V, presented at the output of the divider, steps from the frequency of the faster clock CLK_F to a frequency that is close to the frequency of the slower clock CLK_S. In a step 704, the process 700 changes the clock switch select signal to select the slower clock CLK_S instead of the output of the divider.

The divider does not have to transition through all the intermediate divider values. Instead, the divider values may be stepped up or down to the desired frequency in whatever steps meet the design criteria of a minimal frequency change for a particular implementation. Because active current (I) in a system is proportional to the system capacitance (c), voltage (v), and operating frequency (F) (e.g., I∝cvF), the current variation dI/dt is proportional to frequency change (dI/dt∝cv dF/dt). Thus, smaller frequency changes will always produce a lower dI/dt than is produced by larger frequency changes. Therefore, controlling (e.g., reducing) dF/dt enables the control (e.g., reduction) of dI/dt.

There are many ways to implement the above clock dividers depending on the clocking specifications of the downstream logic. The disclosed examples show just one possible way of implementing the functionality in a general way. However, for the methodology presented herein, the only need is that the divider be “glitchless” when changing the divider values since the divider is sourcing the clock for all the downstream logic while the divider values are being changed. Thus, the output clock waveform needs to be free from stretched or shrunk phase pulses.

The terms “may” and “generally” when used herein in conjunction with “is(are)” and verbs are meant to communicate the intention that the description is exemplary and believed to be broad enough to encompass both the specific examples presented in the disclosure as well as alternative examples that could be derived based on the disclosure. The terms “may” and “generally” as used herein should not be construed to necessarily imply the desirability or possibility of omitting a corresponding element.

While the invention has been particularly shown and described with reference to embodiments thereof, it will be understood by those skilled in the art that various changes in form and details may be made without departing from the scope of the invention.

1. An apparatus comprising:
a glitchless divider configured to generate a first system clock in response to a divider value and a clock signal received from a first source, wherein said divider value changes from a first value to a second value in a predetermined number of steps; and
a glitchless multiplexer configured to select between said first system clock and a second system clock in response to a control signal.

2. The apparatus according to claim 1, wherein said divider value changes from said first value to said second value automatically.

3. The apparatus according to claim 1, wherein said divider value changes from said first value to said second value in response to a user input.

4. The apparatus according to claim 1, wherein said first value is greater than said second value.

5. The apparatus according to claim 1, wherein said first value produces said first system clock having a frequency close to or equal to a frequency of said second system clock.

6. The apparatus according to claim 1, wherein said second system clock is from a second source.

7. The apparatus according to claim 1, further comprise at least one block of state logic that is clocked by an output of said glitchless multiplexer.

8. The apparatus according to claim 1, wherein said clock signal received from said first source has a first frequency and said second system clock has a second frequency.

9. The apparatus according to claim 8, wherein said first frequency is one or more orders of magnitude greater than said second frequency.

10. The apparatus according to claim 1, wherein said clock signal received from said first source has a frequency that is a multiple of a predetermined highest frequency of said first system clock.

11. A method of switching clocks in an electronic circuit comprising:
selecting between a first system clock having a first frequency and a second system clock having a second frequency in response to a control signal;
generating an intermediate clock in response to a divider value and said first system clock; and
changing said divider value from a first value to a second value in a predetermined number of steps to change a frequency of said intermediate clock between said first frequency and said second frequency.

12. The method according to claim 11, further comprising:
selecting the number of predetermined steps to minimize current variation in one or more portions of an integrated circuit caused by switching between said first frequency and said second frequency.

13. The method according to claim 11, wherein a clock waveform seen by one or more portions of said electronic circuit is free from stretched or shrunk phase pulses.

14. The method according to claim 11, wherein said first frequency of said first system clock is a multiple of a predetermined highest frequency of said intermediate clock and changing said divider value from said first value to said second value changes said frequency of said intermediate clock between said predetermined highest frequency and said second frequency.
